(19) United States
(12) Patent Application Publication
(10) Pub. No.: US 2008/0227426 A1
(43) Pub. Date: Sep. 18, 2008

(54) Structure of a car multimedia wireless transmitting and receiving device

(76) Inventor: Chung-Hung Lin, Syuojia Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/717,656

(22) Filed: Mar. 14, 2007

(51) Int. Cl. H05K 11/02

(52) U.S. Cl. 455/345

(57) ABSTRACT

A multimedia wireless transmitting and receiving device includes a main device body, and a base member connected to both the main device body and a car cigarette lighter socket; the main device body has an FM transmitter for transmitting FM signals receivable by a radio of the car; the main device body has a Bluetooth module for performing transference of audio and digital data between the Bluetooth module and a cellular phone; the main device body has a microphone serving as a sound input source; the base member has a plug for connection with the car cigarette lighter socket to obtain power supply; the base member has several connection cavities, which are each used for connection with a respective transfer wire of electronic devices so as to transfer digitized music files stored in the electronic devices to the main device body and to charge the electronic devices.

### BACKGROUND OF THE INVENTION

1. Field of the Invention

The present invention relates to a multimedia wireless transmitting and receiving device for use in a car, more particularly one, which can transform MP3 music files into FM signals receivable by a radio of a car, and can be connected to a cigarette lighter socket of the car for charging various electronic devices connected thereto, and includes a Bluetooth module in order for allowing the driver to make a phone call with a cellular phone in a hand-free mode.

2. Brief Description of the Prior Art

The industry developed “Multimedia Wireless Transmitting And Receiving Devices For Use In A Car” for allowing car drivers to listen to MP3 music in the light of the fact that it is inconvenient for car drivers to wear earphones to listen to digital music sent out by means of digital music players such as personal computers, MP3 players, and cellular phones, and digital music data stored in MP3 format exist in a greater amount, and are more diverse and convenient to use than those stored in conventional compact disks and cassettes, and that passengers of a car can't share MP3 music with the driver if the driver wears earphones to listen to the music.

The car multimedia wireless transmitting and receiving device includes a power input terminal, a voltage stabilizer, a signal conversion and transmission circuit, a signal generator, a signal modulating device, a signal amplifying device, a signal input terminal, and an antenna, and it will transform audio signals transferred from personal electronic products such as portable CD players, PDA, and MP3 players into FM (frequency modulation) signals, and transmit such FM signals, which will be next received by means of radios or equivalents of radios, and sent out to the driver and the passengers through speakers. However, the multimedia wireless transmitting and receiving device doesn't have other additional functions besides allowing audio signals stored in electronic products such as MP3 players to be sent out through the loudspeakers of a car. Consequently, it can't attract the consumers very much.

Furthermore, in order to prevent car drivers from losing concentration to cause an accident as well as preventing them from being fined owing to making phone call with their cellular phones, people developed various devices, which allow car drivers to be on a cellular phone call without having to hold their cellular phones.

In addition, a wide variety of recreational and entertaining electronic devices are available for people, e.g. cellular phones, iPOD, portable storage devices, MP3 players, digital cameras, PDA, palm game devices, and hand-held mobile TV. Such electronic devices will be even more convenient to use if they can be powered/charged through a cigarette lighter socket of a car.

### SUMMARY OF THE INVENTION

It is a main object of the present invention to provide an improvement on a car multimedia wireless transmitting and receiving device to serve more purposes. An embodiment of a multimedia wireless transmitting and receiving device of the present invention is equipped with a Bluetooth module, which can be made to mate and become usable with a cellular phone with Bluetooth function so as to allow the driver to use the cellular phone in a hand-free manner, besides transforming MP3 music files into FM signals and transmitting the FM signals, which will be received, and next sent out as music by a radio of the car. Furthermore, the Bluetooth module can be made to mate and become usable with other electronic devices with Bluetooth function; thus, MP3 music files stored in the electronic devices can be transferred to the Bluetooth module in Bluetooth wireless transference method.

The embodiment of the present invention includes a main device body, and a base member connected to both the main device body and a car cigarette lighter socket. The Bluetooth module is fitted in the main device body. The main device body has an FM transmitter used for transmitting FM signals receivable by the car radio. The main device body has a microphone serving as a sound input source. The base member has a plug for connection with the cigarette lighter socket to obtain power supply. The base member has several connection cavities, which are each used for connection with a respective transfer wire of electronic devices so as to transfer digitized music files stored in the electronic devices to the main device body and to charge the electronic devices. Furthermore, the main device body has an LCD for showing a frequency of radio waves currently transmitted from the FM transmitter, and has a control switch for controlling the main device body.

### BRIEF DESCRIPTION OF THE DRAWINGS

The present invention will be better understood by referring to the accompanying drawings, wherein:

FIG. 1 is a perspective view of the present invention,

FIG. 2 is a circuit block diagram of the present invention,

FIG. 3 is a perspective view of the present invention, used in the first way,

FIG. 4 is a perspective view of the present invention, used in the second way, and

FIG. 5 is a perspective view of the present invention used in the third way.

### DETAILED DESCRIPTION OF THE PREFERRED EMBODIMENTS

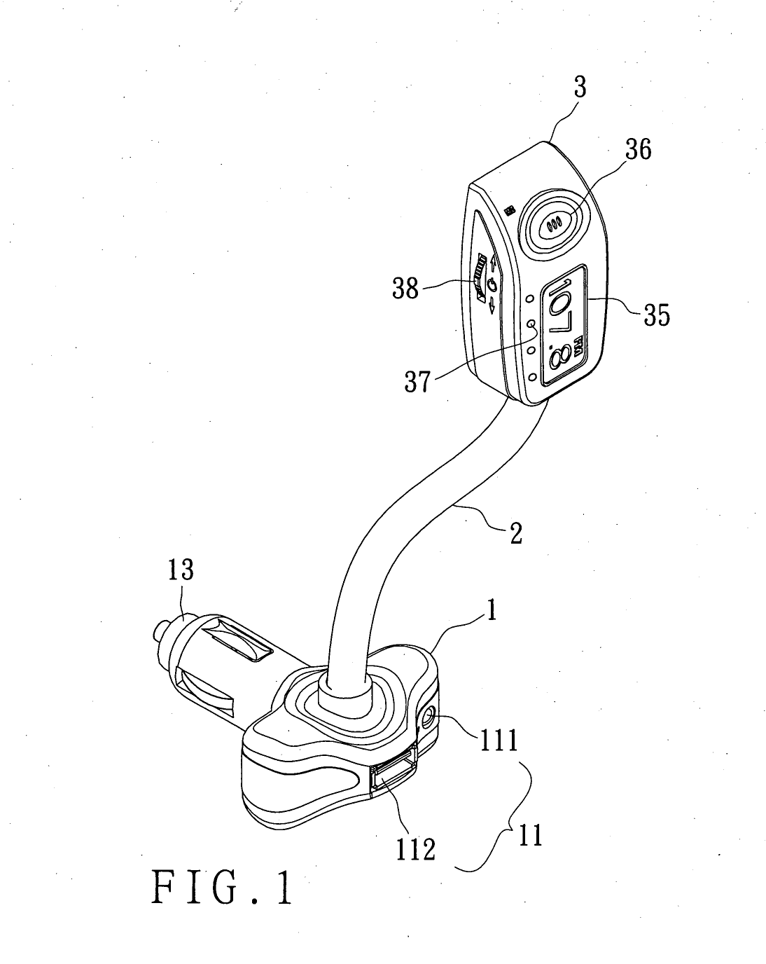

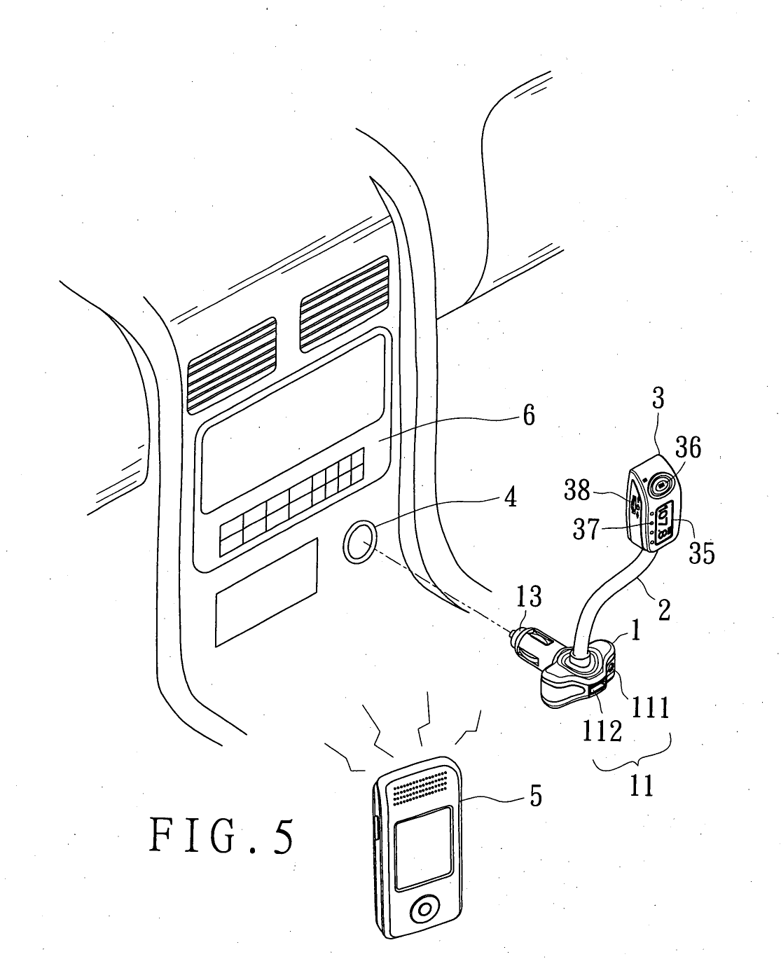

Referring to FIGS. 1, 2 and 5, a preferred embodiment of a car multimedia wireless transmitting and receiving device of the present invention includes a base member 1, a supporting rod 2, and a main device body 3.

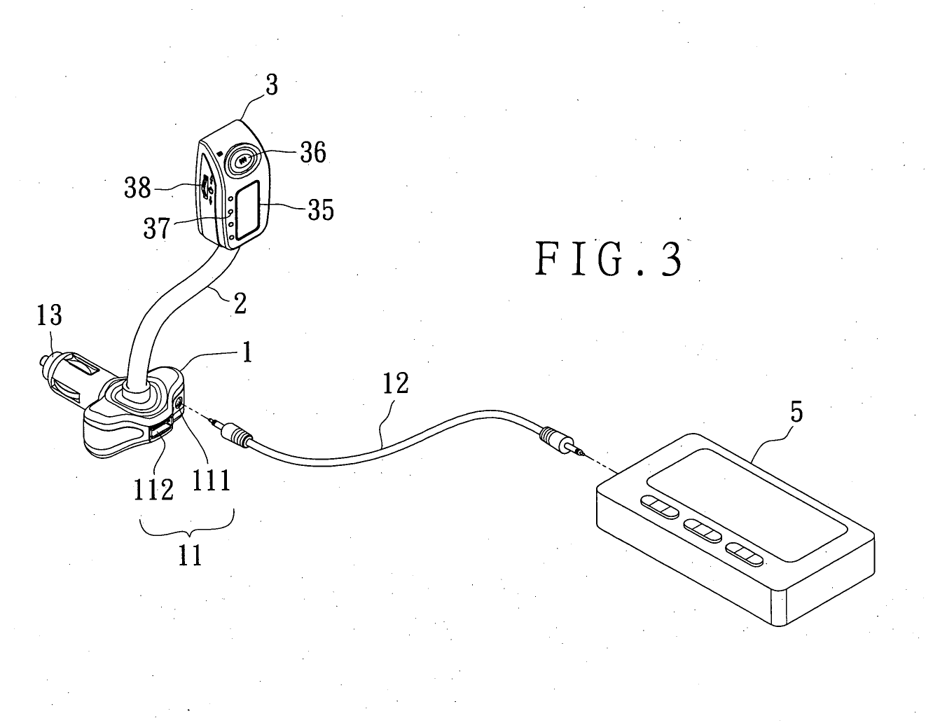

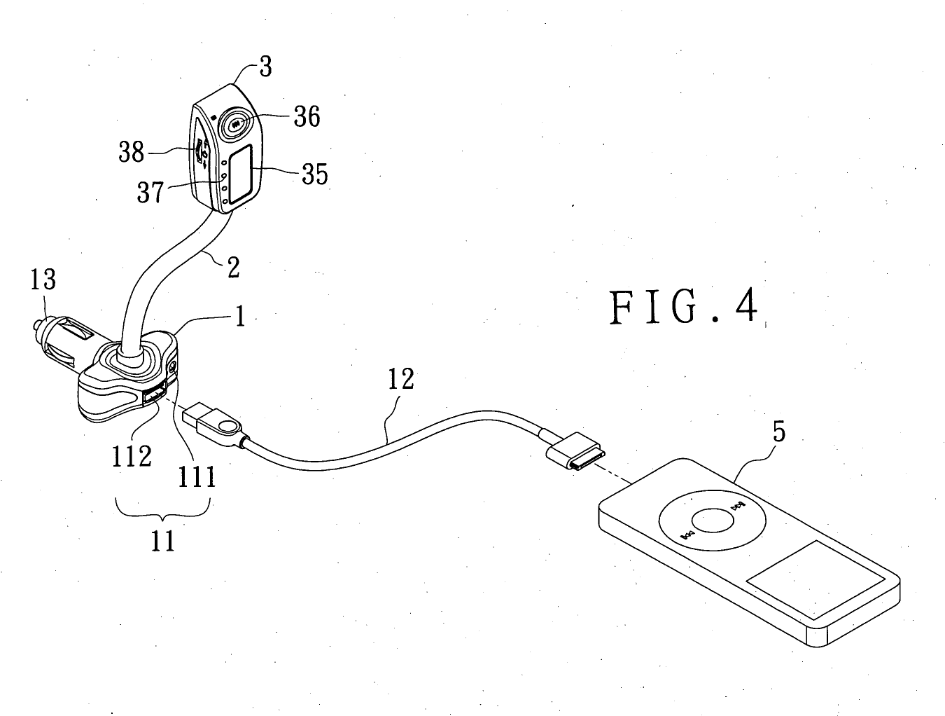

The base member 1 includes a rear plug 13 for connection with a cigarette lighter socket 4 of a car, one or more than one connection sockets 11 such as connection plug holes 111 for a 3.5 mm terminals and USB connection cavities 112. Referring to FIG. 3, audio source outputting electronic devices 5 used with 3.5 mm terminals, e.g. portable CD players and common MP3 players, can be connected to the connection plug holes 111 by means of transfer wires 12 so as to input audio signals to the base member 1. Electronic devices such as cellular phones, iPOD, portable storage devices, MP3 players, digital cameras, PDA, palm game devices and hand-held mobile TV can be connected to the connection cavities 112 by means of respective suitable transfer wires 12 so as to input signals to the base member 1. Referring to FIG. 4, the above-mentioned electronic devices will be charged when they are connected to the base member 1, and the base member 1 is connected to a cigarette lighter socket 4 of a car.

The supporting rod 2 is used to support the main device body 3, and flexible, allowing users to change its shape so as to adjust the position of the main device body 3.

The main device body 3 includes an internal processor 31, a connection interface 32, an FM (frequency modulation) transmitter 33, a Bluetooth module 34, a LCD (liquid crystal display), a microphone 36, several light emitting diodes (LED) 37, and a control switch 38, which are all connected to the processor 31 so as to comprise a circuit. The internal processor 31 is used for transforming digitized music files into audible analogous music signals. The main device body 3 is connected to the base member 1; thus, the circuit is powered by a power source through the base member 1.

The connection interface 32 is connected to the connection sockets 11 of the base member 1, and can be connected to various electronic devices 5 containing MP3 music files by means of different proper transfer wires 12 so that MP3 music files are transferred to the processor 31. The FM transmitter 33 is used for transmitting FM signals, which can be received by means of a radio 6 of a car. The Bluetooth module 34 is provided to perform transference of audio and digital data between it and various electronic devices 5 with Bluetooth function. The liquid crystal display 35 is used for showing the frequency of the radio waves currently transmitted from the FM transmitter 33. The user is allowed to input sound through the microphone 36 when using a cellular phone with Bluetooth function. The light emitting diodes 37 are used to show the current one of various modes such as a music radioing mode and a hand-free mode, wherein the driver is allowed to be on the phone without having to handhold the cellular phone. Furthermore, the light emitting diodes 37 will show the incoming telephone number. The control switch 38 is used for adjusting the frequency of FM signals transmitted from the FM transmitter 33 between 87.9 MHz and 107.9 MHz, and it is used for switching between the music radioing mode and the hand-free mode of talking on a cellular phone.

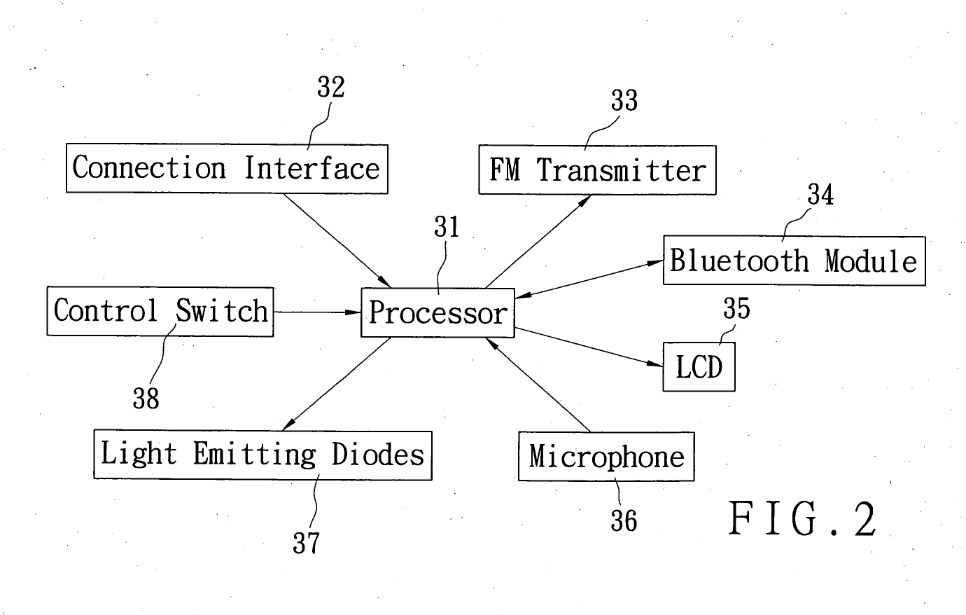

In use, referring to FIG. 2 to FIG. 5, first the plug 13 of the base member 1 is inserted in a cigarette lighter socket 4 of a car in order for the multimedia wireless transmitting and receiving device to obtain power supply. The base member 1 is connected to electronic devices 5 through the transfer wire 12, which electronic devices 5 have connectors connectable with the transfer wire 12, and contain MP3 music files, e.g. cellular phones, iPOD, portable storage devices, and MP3 players; thus, MP3 music files in the electronic devices 5 are read. Next, the internal processor 31 of the main device body 3 transforms the MP3 music files into audible analogous music signals, and the audible analogous music signals are transmitted by means of the FM transmitter 33 so as to be received and sent out through the radio 6 in the car, which has been tuned so as to receive the signals from the FM transmitter 33; thus, the music is sent out through the speakers of the radio 6, and all people can hear the MP3 music in the car. Furthermore, an electronic device 5 will be charged by the cigarette lighter socket 4 of the car through the transfer wire 12 besides transferring audio sources to the base member 1 if the electronic device 5 is connected to the connection cavities 112 of the base member 1.

In order to be capable of making a phone call with a cellular phone in a hand-free manner, referring to FIGS. 1, 2 and 5, first the user makes the Bluetooth module 34 of the main device body 3 match and become usable with a cellular phone with Bluetooth function in respect of radio communication; the Bluetooth module 34 of the main device body 3 will receive signals and send out signals to the processor 31, and the processor 31 will make the light emitting diodes 37 start shining to show that his/her cellular phone is ringing when someone is phoning him/her. Next, the driver presses the control switch 38 of the main device body 3 to answer the phone call and to switch the main device body 3 to the hand-free mode, in which mode the microphone 36 will serve as the sound input source, and the speakers of the radio 6 of the car serve as the sound output source. The driver presses the control switch 38 of the main device body 3 to hang up and switch the main device body 3 to the music radioing mode after the telephone call is finished. In addition, people are allowed to bend the supporting rod 2 so as to adjust the position of the main device body 3 in order for the main device body 3 to be convenient to use.

Referring to FIG. 2 to FIG. 5, the multimedia wireless transmitting and receiving device of the present invention can be used with cellular phones having Bluetooth transference function as well as having MP3 music files stored therein besides being connected and used with cellular phones without Bluetooth function through the transfer wires 12. To use the multimedia wireless transmitting and receiving device together with cellular phones having Bluetooth transference function and MP3 music files stored therein, first the Bluetooth module 34 of the main device body 3 and the cellular phones are made to match with each other in respect of radio communication. Then, MP3 music files stored in the cellular phones are transferred to the main device body 3 in the way of Bluetooth wireless transference. And, the processor 31 of the main device body 3 will transform the MP3 music files into audible analogous music signals, and the audible analogous music signals will be transmitted by means of the FM transmitter 33 so as to be received and sent out through the radio 6 in the car, which has been tuned so as to receive the signals from the FM transmitter 33; thus, the music is sent out through the speakers of the radio 6. In addition, when the cellular phone of the driver is ringing, the driver is allowed to press the control switch 38 of the main device body 3 to switch the main device body 3 to the hand-free mode, in which the driver is on the phone without having to handhold the cellular phone.

From the above description, it can be seen that the present invention has the following advantages:

1. The base member of the car multimedia wireless transmitting and receiving device has connection plug holes and USB connection cavities. Therefore, electronic devices such as cellular phones, iPOD, portable storage devices, and MP3 players can be connected to the base member, and MP3 music files in the electronic devices can be transferred to and transformed into analogous signals by means of the processor of the main device body, which signals will be next transmitted by the FM transmitter. Thus, music is sent out through the speakers of the radio of the car, and the driver and the passengers don't have to wear earphones to listen to MP3 music in the car.

2. The present invention allows the driver to make a phone call with a cellular phone in a hand-free manner; after the driver makes the Bluetooth module of the main device body match and become usable with his/her cellular phone with Bluetooth function in respect of radio communication, he/she is allowed to press the control switch so as to switch the main device body to the hand-free mode, wherein the microphone serves as the sound input source, and the speakers of the radio of the car as the sound output source; thus, the driver doesn't have to hold the cellular phone to make a phone call while driving.

3. The supporting rod of the car multimedia wireless transmitting and receiving device is flexible therefore the user is allowed to adjust the position of the device for the device to be suitable for his/her height.

4. The base member of the car multimedia wireless transmitting and receiving device has connection plug holes and USB connection cavities. Therefore, electronic devices such as cellular phones, iPOD, portable storage devices, MP3 players, digital cameras, PDA, palm game devices, and hand-held mobile TV can be connected to the base member by means of respective suitable transfer wires. Furthermore, after such electronic devices are connected to the connection cavities, they can be charged by means of the cigarette lighter socket of the car besides transferring MP3 music files to the car multimedia wireless transmitting and receiving device through the base member. Therefore, the present invention is very practical.

What is claimed is:

1. An improvement on a structure of a car multimedia wireless transmitting and receiving device, comprising
a main device body, the main device body having an FM transmitter for transmitting FM signals receivable by a radio of a car; the main device body having a Bluetooth module for performing transference of audio and digital data between the Bluetooth module and a cellular phone; the main device body having a microphone serving as a sound input source; the main device body having a liquid crystal display for showing a frequency of radio waves currently transmitted from the FM transmitter; the main device body having a control switch for controlling the main device body;
a base member connected to the main device body, the base member having a plug for connection with a cigarette lighter socket of a car to obtain power supply; the base member having a plurality of connection cavities each used for connection with a respective kind of transfer wire of electronic devices so as to transfer digitized music files stored in said electronic devices to the main device body and to charge said electronic devices.

2. The improvement on a structure of a car multimedia wireless transmitting and receiving device as recited in claim 1, wherein the main device body has a supporting rod on a bottom thereof, and the supporting rod is connected to the base member at a lower end.

3. The improvement on a structure of a car multimedia wireless transmitting and receiving device as recited in claim 2, wherein the supporting rod is flexible.
